(19) United States
(12) Patent Application Publication
(10) Pub. No.: US 2016/0380230 A1
(43) Pub. Date: Dec. 29, 2016

(54) ORGANIC ELECTROLUMINESCENCE DEVICE

(71) Applicant: NITTO DENKO CORPORATION, Ibaraki-shi (JP)

(72) Inventors: Yasumi Yamada, Ibaraki-shi (JP); Yoshinori Osaki, Ibaraki-shi (JP)

(73) Assignee: NITTO DENKO CORPORATION, Ibaraki-shi (JP)

(21) Appl. No.: 14/903,122

(22) PCT Filed: Jun. 19, 2014
(86) PCT No.: PCT/JP2014/066219

§ 371 Date: Jan. 6, 2016

(30) Foreign Application Priority Data
Jul. 12, 2013 (JP) 2013-146386
Jul. 12, 2013 (JP) 2013-146387

(51) Int. Cl. H01L 51/52; H01L 51/56; H01L 51/00

(52) U.S. Cl. CPC H01L 51/5253; H01L 51/5259; H01L 51/0031; H01L 51/56

(57) ABSTRACT

An organic electroluminescence device 1 of the present invention includes a support substrate 2, an organic electroluminescence element 3 provided on the support substrate 2, a moisture absorbing layer 41 which is provided on the organic electroluminescence element 3 and which contains a boron compound, and a moisture barrier layer 51 which is provided on the moisture absorbing layer 41 and which contains a nitrogen compound. In this organic electroluminescence device, a moisture barrier layer and a moisture absorbing layer are hardly peeled off.

### TECHNICAL FIELD

The present invention relates to an organic electroluminescence device.

### BACKGROUND ART

Hereinafter, the organic electroluminescence is referred to as “organic EL”.

Conventionally, the organic EL device including a support substrate and an organic EL element provided on the support substrate is known. The organic EL element includes a first electrode, a second electrode, and an organic layer provided between the first and second electrodes.

The organic EL element is easily degraded by moisture. For example, Patent Document 1 discloses an organic EL device including an organic EL element provided on a support substrate, a moisture absorbing layer provided on the organic EL element, and a gas barrier layer provided on the moisture absorbing layer for preventing degradation of the organic EL element caused by moisture. The moisture absorbing layer in Patent Document 1 is formed of a metal oxide such as calcium oxide or strontium oxide, and the gas barrier layer is formed of silicon nitride, silicon oxide or silicon nitride oxide.

According to the organic EL device in Patent Document 1, permeation of moisture into the organic EL device can be prevented by the gas barrier layer, and further, the moisture absorbing layer provided between the gas barrier layer and the organic EL element absorbs moisture, so that degradation of the organic EL element caused by moisture can be suppressed.

However, when the moisture absorbing layer absorbs moisture, the moisture absorbing layer is expanded in volume. Therefore, the gas barrier layer may be partially peeled off from the moisture absorbing layer, or the gas barrier layer and the moisture absorbing layer may be cracked. When the peeling or cracking occurs, moisture permeates from the affected part into the organic EL element to degrade the organic EL element. Thus, conventional organic EL devices have a short light emission life, and it is required to improve the light emission life.

[Patent Document 1] JP 2011-020335 A

### SUMMARY OF THE INVENTION

An object of the present invention is to provide an organic EL device having a long light emission life by preventing peeling between a moisture barrier layer and a moisture absorbing layer, etc.

An organic EL device of the present invention includes a support substrate, an organic EL element provided on the support substrate, a moisture absorbing layer which is provided on the organic EL element and which contains a boron compound, and a moisture barrier layer which is provided on the moisture absorbing layer and which contains a nitrogen compound.

In a preferable organic EL device of the present invention, a B—N bond moiety exists between the moisture absorbing layer and the moisture barrier layer, wherein the B—N bond moiety is formed by a bond of the boron compound and the nitrogen compound.

In a preferable organic EL device of the present invention, an intermediate layer which is interposed between the moisture absorbing layer and the moisture barrier layer and which contains a compound having a B—N bond is further included.

In a preferable organic EL device of the present invention, the compound having a B—N bond contains boron nitride.

In a preferable organic EL device of the present invention, the intermediate layer is formed by a plasma vacuum vapor deposition method.

In a preferable organic EL device of the present invention, the boron compound contains boron oxide.

In a preferable organic EL device of the present invention, the nitrogen compound contains at least one kind selected from a nitride of a metal or a semimetal, a nitride oxide thereof, a nitride carbide thereof and a nitride carbide oxide thereof.

In a preferable organic EL device of the present invention, the nitrogen compound contains at least one kind selected from a nitride of silicon, a nitride oxide thereof, a nitride carbide thereof and a nitride carbide oxide thereof.

In a preferable organic EL device of the present invention, the moisture barrier layer is formed by a plasma vacuum vapor deposition method.

The organic EL device of the present invention can stably emit light over a long period of time as a moisture barrier layer is hardly peeled off from a moisture absorbing layer.

### BRIEF DESCRIPTION OF THE DRAWINGS

FIG. 1 is a sectional view of an organic EL device of the configuration example 1 of the present invention (sectional view of the organic EL device taken along a thickness direction).

FIG. 2 is a sectional view of an organic EL device of the configuration example 2 of the present invention (sectional view of the organic EL device taken along a thickness direction).

Hereinafter, the present invention will be described with reference to the drawings. It should be noted that dimensions such as a layer thickness and a length in the drawings are different from actual dimensions.

In this specification, the terms “first” and “second” may be added as prefixes. These prefixes, however, are only added in order to distinguish the terms and do not have specific meaning such as order and relative merits. The wording “PPP to QQQ” indicates “PPP or more and QQQ or less”.

The organic EL device of the present invention roughly includes the following first configuration example and second configuration example. Hereinafter, each configuration example is explained, but the organic EL device of the present invention is not limited to these two configuration examples.

### [First Configuration Example of Organic EL Device]

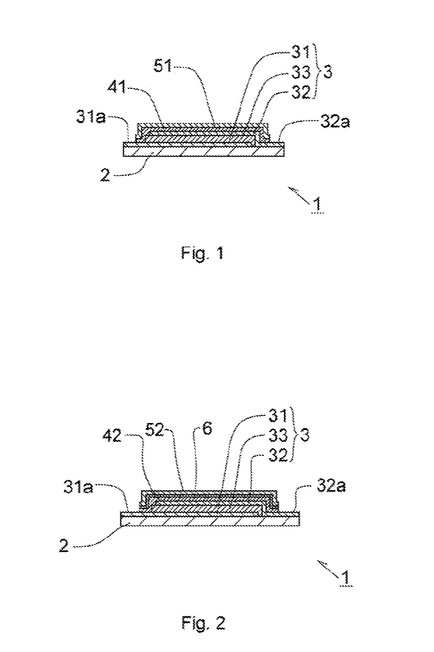

As illustrated in FIG. 1, the organic EL device 1 of the first configuration example includes a support substrate 2, an organic EL element 3 provided on the support substrate 2, a moisture absorbing layer 41 provided on the organic EL element 3, and a moisture barrier layer 51 provided on the moisture absorbing layer 41.

The organic EL element 3 includes a first electrode 31 having a terminal 31a, a second electrode 32 having a terminal 32a, and an organic layer 33 provided between the both electrodes 31 and 32.

For example, the terminal 31a of the first electrode 31 is arranged on a first side and the terminal 32a of the second electrode 32 is arranged on a second side with respect to the organic layer 33. The first side and the second side are mutually opposite sides. The moisture absorbing layer 41 and the moisture barrier layer 51 are stacked and bonded so as to cover a surface of the organic EL element 3 excepting the terminals 31a and 32a.

When the support substrate 2 has electric conductivity, an insulating layer (not illustrated) is provided between the support substrate 2 and the first electrode 31 in order to prevent an electrical short-circuit.

Specifically, the organic EL element 3 is formed into a substantially rectangular shape in a planar view, for example. Of course, a planar shape of the organic EL element 3 is not limited to a substantially rectangular shape, but it may be shaped like a substantially square or circular shape.

The organic layer 33 of the organic EL element 3 includes a light emitting layer, and has various kinds of functional layers such as a hole transport layer and an electron transport layer, as necessary. The layer configuration of the organic layer 33 is described later.

For forming the terminal 31a of the first electrode 31, the organic layer 33 is provided on the surface of the first electrode 31 excepting the end part (terminal 31a) of the first electrode 31 arranged on the first side.

The second electrode 32 is provided on the surface of the organic layer 33 so as to cover the surface of the organic layer 33. For forming the terminal 32a of the second electrode 32, the end part (terminal 32a) of the second electrode 32 is drawn from the end part of the organic layer 33 to the second side.

The terminals 31a and 32a of the first electrode 31 and the second electrode 32 are portions that are connected to the outside. The terminal 31a of the first electrode 31 is an exposed surface of the first electrode 31, and the terminal 32a of the second electrode 32 is an exposed surface of the second electrode 32.

The moisture absorbing layer 41 is a layer that absorbs moisture. By providing the moisture absorbing layer 41, a slight amount of moisture passing through the moisture barrier layer 51 is absorbed into the moisture absorbing layer 41, and therefore degradation of the organic EL element 3 caused by moisture can be effectively suppressed. The moisture absorbing layer 41 is stacked on the second electrode 32. In other words, the moisture absorbing layer 41 is provided between the second electrode 32 and the moisture barrier layer 51.

The moisture barrier layer 51 is a layer for preventing permeation of moisture (water vapor) etc. into the organic EL element 3. The moisture barrier layer 51 is stacked on the moisture absorbing layer 41 so as to cover the moisture absorbing layer 41.

The moisture absorbing layer 41 and the moisture barrier layer 51 airtightly cover the whole of the organic EL element 3 excepting the terminals 31a and 32a. Specifically, the moisture absorbing layer 41 is bonded on a surface of the second electrode 32 excepting the terminals 31a and 32a, and bonded on a peripheral end surface of the organic EL element 3 as illustrated in FIG. 1. The peripheral edge of the moisture absorbing layer 41 is bonded on a surface of the first electrode 31 and a surface of the second electrode 32. The peripheral end surface of the organic EL element 3 is a peripheral surface that forms a thickness of the element 3. Since the moisture barrier layer 51 is stacked on the outside of the moisture absorbing layer 41, the peripheral end surface of the organic EL element 3 is also covered with the moisture barrier layer 51.

In the example illustrated in FIG. 1, the moisture absorbing layer 41 and the moisture barrier layer 51 are provided so as to cover even the peripheral end surface of the organic EL element 3, but the moisture absorbing layer 41 and/or the moisture barrier layer 51 may be provided so as to cover only a surface of the second electrode 32 without covering the peripheral end surface of the organic EL element 3 (not illustrated).

Any appropriate functional layer may be provided between the support substrate 2 and the organic EL element 3, or between the organic EL element 3 and the moisture absorbing layer 41, or on a surface of the moisture barrier layer 51 (the functional layer is not illustrated).

### [Second Configuration Example of Organic EL Device]

As illustrated in FIG. 2, the organic EL device 1 of the second configuration example includes a support substrate 2, an organic EL element 3 provided on the support substrate 2, a moisture absorbing layer 42 provided on the organic EL element 3, an intermediate layer 6 provided on the moisture absorbing layer 42, and a moisture barrier layer 52 provided on the intermediate layer 6.

The organic EL device 1 of the second configuration example is different from the organic EL device 1 of the first configuration example in the point that the intermediate layer 6 is provided between the moisture absorbing layer 42 and the moisture barrier layer 52. Therefore, since the support substrate 2, the first electrode 31 with a terminal 31a, the second electrode 32 with a terminal 32a and the organic layer 33 in the organic EL device 1 of the second configuration example are the same in constitution as those in the organic EL device 1 of the first configuration example, the description for the constitution thereof will be omitted.

The moisture absorbing layer 42 is a layer that absorbs moisture. By providing the moisture absorbing layer 42, a slight amount of moisture passing through the moisture barrier layer 52 and the intermediate layer 6 is absorbed into the moisture absorbing layer 42, and therefore degradation of the organic EL element 3 caused by moisture can be effectively suppressed. The moisture absorbing layer 42 is stacked on the second electrode 32.

The moisture barrier layer 52 is a layer for effectively preventing permeation of moisture (water vapor) etc. into the organic EL element 3. The moisture barrier layer 52 is stacked on the intermediate layer 6 so as to cover the moisture absorbing layer 42.

The intermediate layer 6 functions as a binder layer for integrating the moisture absorbing layer 42 and the moisture barrier layer 52. The intermediate layer 6 may be provided so as to exist in a part of the gap between the moisture absorbing layer 42 and the moisture barrier layer 52, but preferably, the intermediate layer 6 is provided so as to exist in the whole of the gap between the moisture absorbing layer 42 and the moisture barrier layer 52.

The moisture absorbing layer 42, the intermediate layer 6, and the moisture barrier layer 52 cover airtightly the whole of the organic EL element 3 excepting the terminals 31a and 32a. Specifically, the moisture absorbing layer 42 is bonded on a surface of the second electrode 32 excepting the terminals 31a and 32a, and bonded on a peripheral end surface of the organic EL element 3 as illustrated in FIG. 2. The peripheral edge of the moisture absorbing layer 42 is bonded on a surface of the first electrode 31 and a surface of the second electrode 32. The peripheral end surface of the organic EL element 3 is a peripheral surface that forms a thickness of the element 3. Since the moisture barrier layer 52 is stacked on the outside of the moisture absorbing layer 42, the peripheral end surface of the organic EL element 3 is also covered with the moisture barrier layer 52.

In the example illustrated in FIG. 2, the moisture absorbing layer 42, the intermediate layer 6, and the moisture barrier layer 52 are provided so as to cover even the peripheral end surface of the organic EL element 3, but the moisture absorbing layer 42, and/or the intermediate layer 6, and/or the moisture barrier layer 52 may be provided so as to cover only a surface of the second electrode 32 without covering the peripheral end surface of the organic EL element 3 (not illustrated).

Any appropriate functional layer may be provided between the support substrate 2 and the organic EL element 3, or between the organic EL element 3 and the moisture absorbing layer 42, or on a surface of the moisture barrier layer 52 (the functional layer is not illustrated).

### [Support Substrate]

The support substrate is a sheet-shaped material, preferably a flexible sheet-shaped material. The support substrate may be either transparent or opaque. However, a transparent support substrate is used when a bottom-emission type organic EL device is formed. Either a transparent support substrate or an opaque support substrate may be used when a top-emission type organic EL device is formed. The transparency means colorless transparency or colored transparency. The index for the transparency may be, for example, a total light transmittance of 70% or more, preferably 80% or more. It is to be noted that the total light emittance is measured by a measurement method conforming to JIS K7105

### (Method for Testing Optical Characteristics of Plastics).

The support substrate to be used in the present invention is a substrate which is excellent in gas barrier properties so that permeation of water vapor and oxygen can be prevented. For example, the support substrate may be appropriately selected from a metal sheet, a resin sheet, a glass sheet, a ceramic sheet, and the like. In this specification, the “sheet” also includes what is generally called a “film”. The metal sheet is not particularly limited, and examples thereof include flexible thin plates composed of stainless steel, copper, titanium, aluminum, alloys, and the like. A thickness of the metal sheet is 10 μm to 100 μm, for example. The resin sheet is not particularly limited, and examples thereof include flexible synthetic resin sheets such as those of polyester-based resins such as polyethylene terephthalate (PET), polyethylene naphthalate (PEN), and polybutylene terephthalate (PBT); olefin-based resins having an α-olefin as a monomer component, such as polyethylene (PE), polypropylene (PP), polymethylpentene (PMP), ethylene-propylene copolymers, and ethylene-vinyl acetate copolymers (EVA); polyvinyl chloride (PVC); vinyl acetate-based resins; polycarbonate (PC); polyphenylene sulfide (PPS); amide-based resins such as polyamide (nylon) and wholly aromatic polyamide (aramid); polyimide-based resins; and polyether ether ketone (PEEK). A thickness of the resin sheet is not particularly limited, and is, for example, 10 μm to 200 μm. A known gas barrier layer may be stacked on at least one surface of the resin sheet so that satisfactory gas barrier properties can be imparted.

For preventing a rise in temperature of the organic EL device at the time of driving, the support substrate is preferably excellent in heat dissipation. When a conductive substrate (metal sheet etc.) is used as the support substrate, an insulating layer is provided on a surface of the support substrate for insulating the support substrate against an opposite electrode.

[Moisture Absorbing Layer]

The moisture absorbing layer contains a boron compound. With regard to the moisture absorbing layer, provided that the layer contains a boron compound, another compound may be contained therein. Another compound mentioned above refers to a compound other than the boron compound.

Examples of the moisture absorbing layer include (a) a layer substantially containing only a boron compound having moisture absorbing properties, (b) a layer containing a boron compound having moisture absorbing properties and another compound having moisture absorbing properties, (c) a layer containing a boron compound having moisture absorbing properties and another compound not having moisture absorbing properties, (d) a layer containing a boron compound having moisture absorbing properties, another compound not having moisture absorbing properties and another compound having moisture absorbing properties, (e) a layer containing a boron compound not having moisture absorbing properties and another compound having moisture absorbing properties, and the like. In this connection, the moisture absorbing properties refer to a nature of allowing a substance to chemically absorb moisture from the surroundings.

In the present invention, preferred is any one of a moisture absorbing layer substantially containing only a boron compound having moisture absorbing properties, a moisture absorbing layer containing a boron compound having moisture absorbing properties and another compound not having moisture absorbing properties or a moisture absorbing layer containing a boron compound having moisture absorbing properties and not containing another compound having moisture absorbing properties, and in particular, more preferred is a moisture absorbing layer substantially containing only a boron compound having moisture absorbing properties.

In this connection, “substantially containing only a boron compound” means that existence of a very small amount of other compounds that are inevitably contained is allowed, and existence of a significant amount of other compounds is excluded.

The boron compound is a compound containing a boron atom in the molecule thereof, and examples thereof include oxides of boron, oxygen acids of boron and bromides of boron. Examples of the oxide of boron include boron oxide (B₂O₃). The oxygen acid of boron is an oxygen acid with a boron atom as a central atom, or a salt thereof. Examples of the oxygen acid of boron include orthoboric acid, metaboric acid, hypoboric acid, tetraboric acid, pentaboric acid, and sodium salts, potassium salts and ammonium salts thereof. Examples of the bromide of boron include boron tribromide (BBr₃). Among them, boron oxide is preferable because it is excellent in moisture absorbing. Boron oxide is also excellent in transparency, and therefore suitable as a formation material of a moisture absorbing layer of a top-emission type organic EL device.

Another compound having the above-mentioned moisture absorbing properties may be either organic or inorganic, but inorganic compounds are generally used. Examples of another compound having the moisture absorbing properties include alkali metals; alkali earth metals; and oxides, fluorides, sulfates, halides, phosphates, sulfides or perchlorates of alkali metals or alkali earth metals. Examples of the alkali metal or alkali earth metal include Li, Na, K, Rb, Cs, Fr, Be, Mg, Ca, Sr, and Ba. Examples of the oxide of an alkali metal or alkali earth metal include sodium oxide, potassium oxide, calcium oxide, barium oxide and magnesium oxide. Examples of the fluoride of an alkali metal etc. include lithium fluoride, calcium fluoride, magnesium fluoride, and sodium fluoride. Examples of the sulfate of an alkali metal etc. include lithium sulfate, sodium sulfate, and calcium sulfate. Examples of the halide of an alkali metal etc. include calcium chloride, magnesium chloride, and calcium bromide. Examples of the phosphate of an alkali metal etc. include calcium phosphate. Examples of the sulfide of an alkali metal etc. include carbon sulfide and zinc sulfide. Examples of the perchlorate of an alkali metal etc. include barium perchlorate and magnesium perchlorate.

In the case where the moisture absorbing layer contains a boron compound and another compound, the amount of the boron compound is not particularly limited. For example, the amount of the boron compound is greater than or equal to 50% by mass and less than 100% by mass and preferably 60% by mass to 99% by mass relative to the whole moisture absorbing layer. By allowing the moisture absorbing layer to contain a boron compound in an amount lying within the above-mentioned range, larger numbers of B—N bond moieties can be formed between the moisture absorbing layer and the moisture barrier layer in the first configuration example, and the moisture absorbing layer and the intermediate layer are more strongly bonded together in the second configuration example.

A thickness of the moisture absorbing layer is not particularly limited, and is, for example, 5 nm to 500 nm, preferably 30 nm to 200 nm.

### [Moisture Barrier Layer]

The moisture barrier layer contains a nitrogen compound. The moisture barrier layer may contain compounds other than a nitrogen compound or may substantially contain only a nitrogen compound as long as it contains a nitrogen compound. Here, “substantially containing only a nitrogen compound” means that existence of a very small amount of compounds other than a nitrogen compound that are inevitably contained is allowed, and existence of a significant amount of other compounds is excluded.

The nitrogen compound is a compound allowing a nitrogen atom to be contained in its molecule, and examples thereof include a nitrogen-containing inorganic compound. As the nitrogen compound, a nitrogen-containing inorganic compound is preferred because the moisture barrier layer can be formed by a vacuum vapor deposition method.

Examples of the nitrogen-containing inorganic compound include a nitride of a metal or a semimetal, a nitride oxide of a metal or a semimetal, a nitride carbide of a metal or a semimetal, and a nitride carbide oxide of a metal or a semimetal. Examples of the metal include the above-mentioned alkali metals and alkali earth metals, and other metals. Examples of metals other than alkali metals and alkali earth metals include titanium, aluminum, zinc, gallium, and indium. The semimetal is a substance having a nature that is somewhere between a metal and a nonmetal. Examples of the semimetal include silicon, germanium, arsenic, antimony, and tellurium. The moisture barrier layer preferably includes at least one selected from a nitride, a nitride oxide, a nitride carbide, and a nitride carbide oxide of a metal or a semimetal, more preferably at least one selected from a nitride, a nitride oxide, a nitride carbide, and a nitride carbide oxide of silicon. The nitride, nitride oxide, nitride carbide, and nitride carbide oxide of silicon may be silicon nitride, silicon nitride oxide, silicon nitride carbide, and silicon nitride carbide oxide, respectively.

A thickness of the moisture barrier layer is not particularly limited, and is, for example, 50 nm to 2000 nm, preferably 100 nm to 1000 nm.

In the organic EL device of the first configuration example, B—N bond moieties formed by a bond of the boron of a boron compound and the nitrogen of a nitrogen compound exist between the moisture absorbing layer and the moisture barrier layer. The interface between the moisture absorbing layer and the moisture barrier layer and the vicinity thereof are dotted with the B—N bond moieties and are preferably dotted with the B—N bond moieties evenly distributed.

### [Intermediate Layer]

The intermediate layer in the second configuration example contains a compound having a B—N bond. It is preferred that the intermediate layer contain boron nitride (a kind of the compound having a B—N bond), and furthermore, another compound other than the compound having a B—N bond may be contained therein. Since the intermediate layer is strongly bonded to both of the moisture barrier layer and the moisture absorbing layer, it is preferred that another compound mentioned above be at least any one of the boron compound and the nitrogen compound. Hereinafter, a compound having a B—N bond is referred to as “a B—N compound”.

Examples of the B—N compound typically include boron nitride described above. Other examples of the B—N compound include boron aluminum nitride, boron gallium nitride, and the like.

The thickness of the intermediate layer is not particularly limited, and for example, the thickness thereof is 1 nm to 100 nm. In the case where boron nitride is used as a formation material of the intermediate layer, it is preferred that the intermediate layer be formed as thin as possible. This is because the intermediate layer containing boron nitride shuts off light in the case of constituting a top-emission type organic EL device since boron nitride is poor in transparency. The thickness of the intermediate layer which contains boron nitride or is composed of boron nitride is preferably 1 nm to 10 nm and is more preferably 5 nm to 10 nm.

### [Organic EL Element Having First Electrode, Organic Layer and Second Electrode]

The first electrode may be either an anode or a cathode. The first electrode is an anode, for example.

The formation material of the first electrode (anode) is not particularly limited, and examples include indium tin oxide (ITO); indium tin oxide including silicon oxide (ITSO); aluminum; gold; platinum; nickel; tungsten; copper; and an alloy. When a bottom-emission type organic EL device is formed, a transparent first electrode is used.

A thickness of the first electrode is not particularly limited, and is usually 0.01 μm to 1.0 μm.

An organic layer has a laminate structure composed of at least two layers. Examples of a structure of the organic layer include (A) a structure composed of three layers including a hole transport layer, a light emitting layer, and an electron transport layer; (B) a structure composed of two layers including a hole transport layer and a light emitting layer; and (C) a structure composed of two layers including a light emitting layer and an electron transport layer.

In the organic layer of the above-mentioned (B), the light emitting layer also works as an electron transport layer. In the organic layer of the above-mentioned (C), the light emitting layer also works as a hole transport layer.

The organic layer used in the present invention can have any of the structures (A) to (C) mentioned above.

The organic layer having the structure (A) in the case of where the first electrode is an anode is explained below.

The hole transport layer is provided on the surface of the first electrode. An arbitrary function layer other than the first electrode and the hole transport layer may be interposed between the first electrode and the hole transport layer under the conditions in which the light emitting efficiency of the organic EL element is not lowered.

For example, the hole injection layer may be provided on the surface of the first electrode, and the hole transport layer may be provided on the surface of the hole injection layer. The hole injection layer is a layer having a function of aiding injection of a hole from the anode layer to the hole transport layer.

A formation material of the hole transport layer is not particularly limited as long as the formation material has a hole transport function. Examples of the formation material of the hole transport layer include an aromatic amine compound such as 4,4′,4″-tris(carbazole-9-yl)-triphenyl amine (abbreviation: TcTa); a carbazole derivative such as 1,3-bis(N-carbazolyl) benzene; a spiro compound such as N,N′-bis(naphthalene-1-yl)-N,N′-bis(phenyl)benzidine (abbreviation: α-NPD) and N,N′-bis(naphthalene-1-yl)-N,N′-bis(phenyl)-9,9′-spiro-bisfluorene (abbreviation: Spiro-NPB); a polymer compound; and the like. The formation material of the hole transport layer may be used alone or in combination of two or more formation materials. Furthermore, the hole transport layer may have a multi-layer structure including two or more layers.

A thickness of the hole transport layer is not particularly limited, but the thickness of 1 nm to 500 nm is preferable from the viewpoint of reducing drive voltage.

A light emitting layer is provided on the surface of the hole transport layer.

A formation material of the light emitting layer is not particularly limited as long as it has light emitting properties. Examples of the formation material of the light emitting layer include a low molecular light emission material such as a low molecular fluorescence emission material and a low molecular phosphorescence emission material.

Examples of the low molecular light emission material include an aromatic dimethylidene compound such as 4,4′-bis(2,2′-diphenyl vinyl)-biphenyl (abbreviation: DPVBi); an oxadiazole compound such as 5-methyl-2-[2-[4-(5-methyl-2-benzoxazolyl)phenyl]vinyl]benzoxazole; a triazole derivative such as 3-(4-biphenyl-yl)-4-phenyl-5-t-butyl phenyl-1,2,4-triazole; a styryl benzene compound such as 1,4-bis(2-methyl styryl)benzene; a benzoquinone derivative; a naphthoquinone derivative; an anthraquinone derivative; a fluorenone derivative; an organic metal complex such as an azomethine-zinc complex, tris(8-quinolinolato) aluminum (Alq₃), and the like.

Furthermore, as the formation material of the light emitting layer, a host material doped with light emitting dopant material may be used.

For the host material, for example, the above-mentioned low molecular light emission material can be used, and, other than this, a carbazole derivative such as 1,3,5-tris(carbazo-9-yl)benzene (abbreviation: TCP), 1,3-bis(N-carbazolyl)benzene (abbreviation: mCP), 2,6-bis(N-carbazolyl)pyridine, 9,9-di(4-dicarbazole-benzyl)fluorene (abbreviation: CPF), 4,4′-bis(carbazole-9-yl)-9,9-dimethyl-fluorene (abbreviation: DMFL-CBP), and the like can be used.

Examples of the dopant material include a styryl derivative; a perylene derivative; a phosphorescence emission metal complex including an organic iridium complex such as tris(2-phenyl pyridyl)iridium (III) (Ir(ppy)₃), tris(1-phenyl isoquinoline)iridium (III) (Ir(piq)₃), and bis(1-phenyl isoquinoline) (acetylacetonato) iridium (III) (abbreviation: Ir(piq)₂(acac)), and the like.

Furthermore, the formation material of the light emitting layer may include such as the formation material of the hole transport layer mentioned above, the formation material of the electron transport layer mentioned below, and various additives.

A thickness of the light emitting layer is not particularly limited, and is, for example, preferably 2 nm to 500 nm.

The electron transport layer is provided on the surface of the light emitting layer. An arbitrary function layer other than the second electrode and the electron transport layer may be interposed between the second electrode and the electron transport layer under the conditions in which the light emitting efficiency of the organic EL element is not lowered.

For example, the electron injection layer may be provided on the surface of the electron transport layer, and the second electrode may be provided on the surface of the electron injection layer. The electron injection layer is a layer having a function of aiding injection of an electron from the second electrode to the electron transport layer.

A formation material of the electron transport layer is not particularly limited as long as it is a material having an electron transport function. Examples of the formation material of the electron transport layer include a metal complex such as tris(8-quinolinolato) aluminum (abbreviation: Alq₃), bis(2-methyl-8-quinolinolato)(4-phenyl phenolate) aluminum (abbreviation: BAlq); a heteroaromatic compound such as 2,7-bis[2-(2,2′-bipyridine-6-yl)-1,3,4-oxadiazo-5-yl]-9,9-dimethyl fluorene (abbreviation: Bpy-FOXD), 2-(4-biphenylyl)-5-(4-tert-butyl phenyl)-1,3,4-oxadiazole (abbreviation: PBD), 1,3-bis[5-(p-tert-butyl phenyl)-1,3,4-oxadiazole-2-yl]benzene (abbreviation: OXD-7), and 2,2′,2″-(1,3,5-phenylene)-tris(1-phenyl-1H-benzimidazole) (abbreviation: TPBi); and a polymer compound such as poly(2,5-pyridine-diyl) (abbreviation: PPy). The formation material of the electron transport layer may be used alone or in combination of two or more types. Furthermore, the electron transport layer may have a multi-layered structure including two or more layers.

A thickness of the electron transport layer is not particularly limited, and is preferably 1 nm to 500 nm from the viewpoint of reducing drive voltage.

A second electrode may be either a cathode or an anode. The second electrode is a cathode, for example.

A formation material of the second electrode is not particularly limited, but a transparent second electrode is used when a top-emission type organic EL element is formed. Examples of the formation material of the second electrode which is transparent and has electric conductivity include indium tin oxide (ITO); indium tin oxide including silicon oxide (ITSO); zinc oxide in which electric conductive metal such as aluminum is added (ZnO:Al); and a magnesium-silver alloy, and the like. A thickness of the second electrode is not particularly limited, and is usually 0.01 μm to 1.0 μm.

### [Use and Effect of Organic EL Device]

The organic EL device of the present invention, alone or in combination of two or more of the organic EL devices, can be used as a light emitting panel of an illuminating device or an image display.

The organic EL device of the present invention is provided with a moisture barrier layer, so that permeation of moisture into the device can be prevented. Further, a moisture absorbing layer is provided between the organic EL element and the moisture barrier layer, and therefore when a slight amount of moisture passes through the moisture barrier layer, the moisture absorbing layer absorbs the moisture. Accordingly, permeation of moisture into the organic EL element can be prevented.

The organic EL device of the present invention hardly allows an organic EL element to be deteriorated due to moisture and stably emits light for a long period of time. In the following Examples and Comparative Examples, it has been verified that such an organic EL device stably emits light for a long period of time. While the reason that the organic EL device of the present invention has a long light emission lifetime has not yet been elucidated, by the present inventors, the reason is presumed to be as follows. Of course, since the following matter is only a presumption, the possibility that the reason is based on a matter different from the following matter also cannot be denied.

Generally, as the moisture absorbing layer absorbs moisture while using the organic EL device, the moisture absorbing layer is expanded to distort the moisture barrier layer. As a result, the moisture barrier layer is partially peeled off from the moisture absorbing layer, or the moisture barrier layer and the moisture absorbing layer are cracked. Moisture permeates from the peeled part or cracked part into the organic EL element.

With regard to the organic EL devices of the first configuration example and second configuration example, the moisture absorbing layer contains a boron compound and the moisture barrier layer contains a nitrogen compound.

In the organic EL device of the first configuration example, it is presumed that the boron atom of a boron compound and the nitrogen atom of a nitrogen compound form a B—N bond. In this connection, it is presumed that all boron compound molecules contained in the moisture absorbing layer and all nitrogen compound molecules contained in the moisture barrier layer are not wholly bonded together through the B—N bond moiety, and a plurality of molecules existing in the interface between the moisture absorbing layer and the moisture barrier layer and the vicinity thereof is bonded together through the B—N bond moiety. Since the B—N bond is hardly dissociated by moisture or oxygen as compared to other bonds, even when the moisture absorbing layer absorbs moisture, the moisture absorbing layer and the moisture barrier layer become difficult to separate by virtue of the B—N bond moiety. In this way, by allowing B—N bond moieties to exist in the interface between the moisture absorbing layer and the moisture barrier layer and the vicinity of the interface, the moisture absorbing layer and the moisture barrier layer are united, and as a result thereof, it is possible to effectively prevent a moisture barrier layer from peeling off or effectively prevent a crack from being generated even when the moisture absorbing layer expands. Consequently, it is presumed that the organic EL device of the first configuration example continues to stably emit light for a long period of time.

On the other hand, in the organic EL device of the second configuration example, an intermediate layer containing a B—N compound is provided between the moisture absorbing layer and the moisture barrier layer. The moisture absorbing layer brought into contact with the back surface of the intermediate layer contains a boron compound and the moisture barrier layer brought into contact with the front surface of the intermediate layer contains a nitrogen compound. It is presumed that the boron atom of a boron compound in the moisture absorbing layer forms a B—N bond with the nitrogen atom of a B—N compound in the intermediate layer, and the nitrogen atom of a nitrogen compound in the moisture barrier layer forms a B—N bond with the boron atom of a B—N compound in the intermediate layer. In this connection, it is presumed that all boron compound molecules contained in the moisture absorbing layer and all nitrogen compound molecules contained in the moisture barrier layer do not wholly forms a B—N bond with a B—N compound contained in the intermediate layer, and a plurality of molecules existing in the interface between the moisture absorbing layer and the intermediate layer and the vicinity thereof, and in the interface between the moisture barrier layer and the intermediate layer and the vicinity thereof is bonded together through the B—N bond moiety. As mentioned above, since the B—N bond is hardly dissociated by moisture or oxygen as compared to other bonds, even when the moisture absorbing layer absorbs moisture, the moisture absorbing layer and the intermediate layer, and the moisture barrier layer and the intermediate layer become difficult to separate from each other. In this way, as the moisture absorbing layer and the moisture barrier layer are united through the intermediate layer, it is possible to effectively prevent a moisture barrier layer from peeling off or effectively prevent a crack from being generated even when the moisture absorbing layer expands. Consequently, it is presumed that the organic EL device of the second configuration example continues to stably emit light for a long period of time.

### [Production Method of Organic EL Device of First Configuration]

The production method of the organic EL device of the first configuration example includes the moisture absorbing layer forming step of forming a moisture absorbing layer on an organic EL element formed on a support substrate, and the moisture barrier layer forming step of forming a moisture barrier layer on the moisture absorbing layer.

It is possible to continuously produce a plurality of the organic EL devices of the present invention by a roll-to-roll method and it is also possible to produce the organic EL devices individually.

Hereinafter, a method of continuously producing a plurality of the organic EL devices by a roll-to-roll method will be described.

The production method of the organic EL devices by a roll-to-roll method includes the delivery step of delivering a flexible belt-shaped support substrate, the element forming step of forming a plurality of organic EL elements on the belt-shaped support substrate, the moisture absorbing layer forming step of forming a moisture absorbing layer on the organic EL element, the moisture barrier layer forming step of forming a moisture barrier layer on the moisture absorbing layer, and the winding step of winding a belt-shaped laminated body having the belt-shaped support substrate, the organic EL elements, the moisture absorbing layer and the moisture barrier layer into a roll.

### (Delivery Step)

The delivery step is a step of delivering to a production line a belt-shaped support substrate wound around a roll.

The belt-shaped support substrate is a long and narrow rectangular flexible sheet-shaped material. The length of the belt-shaped support substrate (length in the long direction) is not particularly limited, and is, for example, 10 m to 1000 m, and the width of the support substrate (length in the short direction) is not particularly limited, and is, for example, 10 mm to 300 mm.

### (Element Forming Step)

The step of forming an organic EL element is carried out in the same manner as before.

To explain it briefly, the delivered support substrate is cleaned in a cleaning bath as necessary, and then dried. After the cleaning and drying step, the first electrode is formed on the surface of the support substrate.

As the method for forming the first electrode, an optimum method can be employed depending on the formation material thereof, and examples of the method include a sputtering method, a vacuum vapor deposition method, and an inkjet method. In a case where an anode is formed of metal, the vacuum vapor deposition method is used. Furthermore, the support substrate having the first electrode previously patterned may be used. In the case where the support substrate has the previously formed first electrode, it is cleaned and dried after unwound from the roll.

An organic layer is formed on the surface of the first electrode excepting a terminal thereof. An organic layer can be formed by forming a positive hole transport layer, a light emitting layer, and an electron transport layer in this order on the surface of the first electrode, for example. As the method for forming the positive hole transport layer, the light emitting layer, and the electron transport layer, an optimum method can be employed depending on the formation material thereof, and examples of the method include a sputtering method, a vacuum vapor deposition method, an ink-jet method, a coating method, and the like. Those layers are usually formed by the vacuum vapor deposition method.

Subsequently, the second electrode is formed on the surface of the organic layer. The second electrode is formed so as not to cover the terminal of the first electrode. As the method for forming the second electrode, an optimum method can be employed depending on the formation material thereof, and examples of the method include a sputtering method, a vacuum vapor deposition method, an ink-jet method, and the like.

The interval between the organic EL elements is not particularly limited and may be appropriately set. For example, the interval between the organic EL elements is 0.5 mm to 5 mm.

### (Moisture Absorbing Layer Forming Step)

The moisture absorbing layer forming step is the step of forming a moisture absorbing layer on the organic EL element.

As described above, by allowing a boron compound and other optional compounds to be deposited on the surface of the organic EL element excluding the two electrode terminals, a moisture absorbing layer is formed.

As the method for forming a moisture absorbing layer, an optimum method can be employed according to the kind of the formation material, and examples thereof include a vacuum vapor deposition method such as resistive heating vapor deposition and electron beam vapor deposition, a sputtering method, a heat CVD method, a light CVD method, a plasma CVD method, an MOCVD method, an atomic layer deposition (ALD) method, and the like. Preferably, a vacuum vapor deposition method is utilized to form a moisture absorbing layer.

### (Moisture Barrier Layer Forming Step)

The moisture barrier layer forming step is the step of forming a moisture barrier layer on the moisture absorbing layer.

As described above, by allowing a nitrogen compound and other optional compounds to be deposited on the surface of the moisture absorbing layer, a moisture barrier layer is formed.

As the method for forming a moisture barrier layer, an optimum method can be employed according to the kind of the formation material, and examples thereof include a physical vapor phase growth method or a chemical vapor phase growth method. Of these, it is preferred that a physical vapor deposition method using the plasma or a chemical vapor deposition method using the plasma be utilized to form a moisture barrier layer, and in particular, it is more preferred that a plasma vacuum vapor deposition method be utilized to form a moisture barrier layer.

By employing a method using the plasma as the method for forming a moisture barrier layer, a moisture barrier layer having larger numbers of B—N bond moieties can be formed. For details, when the plasma is used, the surface of a moisture absorbing layer which is the mating surface is activated. By allowing the surface of a moisture absorbing layer to be activated, a boron compound in the moisture absorbing layer becomes easy to react with a nitrogen compound which is a formation material of the moisture barrier layer. As a result thereof, a moisture barrier layer having larger numbers of B—N bond moieties in the interface against the moisture absorbing layer or the vicinity of the interface can be formed.

The plasma is not particularly limited, and for example, an are discharge plasma, a glow discharge plasma, or the like may be used. An are discharge plasma is preferably used because a very high electron density is achieved unlike a glow discharge plasma. By using an are discharge plasma, reactivity of a nitrogen compound can be increased and a moisture barrier layer having larger numbers of B—N bond moieties can be formed on the moisture absorbing layer.

As an are discharge plasma generation source, for example, a pressure gradient type plasma gun, a direct-current discharge plasma generator, a high-frequency discharge plasma generator, or the like may be used. Among them, a pressure gradient type plasma gun is preferably used as a plasma source because a high-density plasma can be stably generated.

As a plasma vapor deposition apparatus for forming a moisture barrier layer, a conventionally known one can be used.

In a nutshell, the plasma vapor deposition apparatus has a chamber allowing the inside to be kept at vacuum, a transport device for continuously sending a belt-shaped support substrate, a plasma source which generates plasma, an evaporation source containing the material, a reactant gas supplying device for supplying the inside of the chamber with a reactant gas, a discharge gas supplying device for supplying the inside of the chamber with a discharge gas, and a vacuum pump allowing the inside of the chamber to be kept at a vacuum state. The evaporation source is usually installed in the bottom part of the chamber so as to face the support substrate transported. As a means for allowing the material contained in the evaporation source to evaporate, the plasma can be used, and resistive heating or an electron beam may be used.

When the moisture barrier layer containing at least one selected from a nitride, a nitride oxide, a nitride carbide, and a nitride carbide oxide of a metal or a semimetal is formed, a metal or a semimetal, or a nitride, a nitride oxide, a nitride carbide or a nitride carbide oxide of a metal or a semimetal is put in the evaporation source, for example. When a metal or a semimetal is put in the evaporation source, by using a nitrogen-containing gas, a nitrogen-oxygen-containing gas, a nitrogen-hydrocarbon-containing gas, or a nitrogen-oxygen-hydrocarbon-containing gas as a reaction gas, the moisture barrier layer can be formed containing a nitride of a metal or a semimetal and the like. Examples of the nitrogen-containing gas include nitrogen (N₂), ammonia (NH₃), and nitrogen monoxide (NO). Examples of the nitrogen-oxygen-containing gas include nitrogen monoxide (NO), dinitrogen monoxide (N₂O), mixed gases of nitrogen (N₂) and oxygen (O₂). Examples of the nitrogen-hydrocarbon-containing gas include mixed gases of the nitrogen-containing gas and a hydrocarbon-containing gas. Examples of the hydrocarbon-containing gas include methane (CH₄), ethane (C₂H₆), propane (C₃H₈), butane (C₄H₁₀), ethylene (C₂H₄), and acetylene (C₂H₂). Examples of the nitrogen-oxygen-hydrocarbon-containing gas include mixed gases of the nitrogen-containing gas, an oxygen-containing gas, and a hydrocarbon-containing gas, and mixed gases of a nitrogen-oxygen-containing gas and a hydrocarbon-containing gas.

By actuating a vacuum pump, the inside of a chamber is kept at a vacuum state. The pressure in the chamber lies within the range of 0.01 Pa to 0.1 Pa and preferably lies within the range of 0.02 Pa to 0.05 Pa. In the chamber in a vacuum state, a discharge gas is introduced from the discharge gas supplying device to the plasma generation source to generate plasma. Furthermore, by allowing the material to evaporate from the vapor deposition source while introducing a reactant gas from the reactant gas supplying device to the inside of the chamber, it is possible to form a moisture barrier layer on the moisture absorbing layer.

The introduction of a reactant gas and the generation of plasma may be simultaneously performed, or alternatively, the plasma may be generated after the introduction of a reactant gas or a reactant gas may be introduced after the generation of plasma. Since the surface of the moisture absorbing layer can be activated before a formation material of the moisture barrier layer is deposited thereon, it is preferred that a reactant gas be introduced after the generation of plasma.

The deposition rate can be appropriately set, and for example, the deposition rate is 10 to 300 nm/minute.

### (Winding Step)

The winding step is the step of winding a belt-shaped laminated body (a laminate obtained by allowing an organic EL element, a moisture absorbing layer and a moisture barrier layer to be laminated on a belt-shaped support substrate) obtained via the respective steps described above into a roll.

In this way, it is possible to obtain a long object in which a plurality of organic EL devices is connected to one another by a roll-to-roll method. By allowing this long object to be appropriately cut, it is possible to obtain one or two or more organic EL devices of the present invention.

### [Production Method of Organic EL Device of Second Configuration]

The production method of the organic EL device of the second configuration example includes the moisture absorbing layer forming step of forming a moisture absorbing layer on an organic EL element formed on a support substrate, the intermediate layer forming step of forming an intermediate layer on the moisture absorbing layer, and the moisture barrier layer forming step of forming a moisture barrier layer on the intermediate layer.

The production method of the organic EL device of the second configuration example is the same as the production method in the first configuration example except that the production method in the second configuration example further includes the intermediate layer forming step between the moisture absorbing layer forming step and the moisture barrier layer forming step. Therefore, in the description for the production method of the organic EL device of the second configuration example, only a part different from the production method in the first configuration example will be described.

### (Intermediate Layer Forming Step)

The intermediate layer forming step is the step of forming an intermediate layer on the moisture absorbing layer. By allowing a B—N compound and other optional compounds to be deposited on the surface of the moisture absorbing layer after the moisture absorbing layer is formed, an intermediate layer is formed.

As the method for forming an intermediate layer, an optimum method can be employed according to the kind of the formation material, and examples thereof include a physical vapor phase growth method or a chemical vapor phase growth method described above. Of these, it is preferred that a physical vapor deposition method using the plasma or a chemical vapor deposition method using the plasma be utilized to form an intermediate layer, and in particular, it is more preferred that a plasma vacuum vapor deposition method be utilized to form an intermediate layer.

By employing a method using the plasma as the method for forming an intermediate layer, it is possible to form an intermediate layer in which larger numbers of B—N bonds are generated for the moisture absorbing layer. For details, when the plasma is used, the surface of a moisture absorbing layer which is the mating surface is activated. By allowing the surface of a moisture absorbing layer to be activated, a boron compound in the moisture absorbing layer becomes easy to react with a B—N compound which is a formation material of the intermediate layer. As a result thereof, an intermediate layer in which larger numbers of B—N bonds are generated in the interface against the moisture absorbing layer or the vicinity of the interface can be formed.

Moreover, in the production method of the second configuration example, by employing a method using the plasma also as the method for forming a moisture barrier layer, it is possible to form a moisture barrier layer in which larger numbers of B—N bonds are generated for the intermediate layer. For details, when the plasma is used, the surface of an intermediate layer which is the mating surface is activated. By allowing the surface of an intermediate layer to be activated, a B—N compound contained in an intermediate layer becomes easy to react with a nitrogen compound which is a formation material for the moisture barrier layer. As a result thereof, a moisture barrier layer having larger numbers of B—N bond moieties in the interface against the intermediate layer or the vicinity of the interface can be formed.

The plasma is not particularly limited, and for example, an arc discharge plasma, a glow discharge plasma, or the like may be used. An arc discharge plasma is preferably used because a very high electron density is achieved unlike a glow discharge plasma. By using an arc discharge plasma, reactivity of a nitrogen compound can be increased and larger numbers of B—N bond can be generated.

As an arc discharge plasma generation source, for example, a pressure gradient type plasma gun, a direct-current discharge plasma generator, a high-frequency discharge plasma generator, or the like may be used. Among them, a pressure gradient type plasma gun is preferably used as the plasma source because a high-density plasma can be stably generated.

As a plasma vapor deposition apparatus for forming an intermediate layer, such a plasma vapor deposition apparatus exemplified as that for the moisture barrier layer forming step, which has a transport device, a plasma source, an evaporation source, a reactant gas supplying device, a discharge gas supplying device and a vacuum pump, can be used.

In the case of forming an intermediate layer which contains boron nitride, for example, boron is contained in the vapor deposition source, and a nitrogen-containing gas is used as the reactant gas. Examples of the nitrogen-containing gas include nitrogen (N₂), ammonia (NH₃), nitrogen monoxide (NO) or the like.

By actuating a vacuum pump, the inside of a chamber is kept at a vacuum state. The pressure in the chamber lies within the range of 0.01 Pa to 0.1 Pa and preferably lies within the range of 0.02 Pa to 0.05 Pa. In the chamber in a vacuum state, a discharge gas is introduced from the discharge gas supplying device to the plasma generation source to generate plasma. Furthermore, by allowing the material to evaporate from the vapor deposition source while introducing a reactant gas from the reactant gas supplying device to the inside of the chamber, it is possible to form an intermediate layer on the moisture absorbing layer.

The introduction of a reactant gas and the generation of plasma may be simultaneously performed, or alternatively, the plasma may be generated after the introduction of a reactant gas or a reactant gas may be introduced after the generation of plasma. Since the surface of the moisture absorbing layer can be activated before a formation material of the intermediate layer is deposited thereon and the surface of the intermediate layer can be activated before a formation material of the moisture barrier layer is deposited thereon, it is preferred that a reactant gas be introduced after the generation of plasma.

The deposition rate can be appropriately set, and for example, the deposition rate is 10 to 300 nm/minute.

### EXAMPLES

Hereinafter, the present invention is described in detail with reference to following Examples and Comparative Examples. However, the present invention is not limited to the following Examples.

### Example 1

### Formation of Organic EL Element

On the surface of a commercially available glass substrate, an anode was formed by allowing aluminum to be vapor deposited under vacuum to 150 nm in thickness. Next, on the surface of the anode, a hole injection layer was formed by allowing HATCN (hexa-azatriphenylene-hexacarbonitrile) to be vapor deposited under vacuum to 40 nm in thickness. On the surface of this hole injection layer, a hole transport layer was formed by allowing α-NPD (N,N′-bis(naphthalene-1-yl)-N,N′-bis(phenyl)benzidine) to be vapor deposited under vacuum to 30 nm in thickness. On the surface of this hole transport layer, a light emitting layer was formed by allowing Alq₃ (tris(8-quinolinolato)aluminum) to be vapor deposited under vacuum to 60 nm in thickness. On the surface of this light emitting layer, an electron injection layer was formed by allowing lithium fluoride to be vapor deposited under vacuum to 1 nm in thickness. On the surface of this electron injection layer, a cathode was formed by allowing an alloy of magnesium and silver (magnesium:silver (mole ratio)=9:1) to be vapor deposited under vacuum to 5 nm in thickness.

### (Formation of Moisture Absorbing Layer and Moisture Barrier Layer)

On the surface of the cathode layer, a moisture absorbing layer was formed by allowing B₂O₃ (boron oxide) to be plasma vapor deposited under vacuum to 60 nm in thickness.

On the surface of the moisture absorbing layer, a moisture barrier layer was formed by allowing SiN_{X} (silicon nitride) to be plasma vapor deposited under vacuum to 300 nm in thickness. For the plasma vapor deposition, a pressure gradient-type plasma gun was used as a plasma source, silicon particles were used as an evaporation source, nitrogen gas (N₂) was used as reaction gas, and a vapor deposition rate was 50 nm/minute.

In this manner, a top-emission type organic EL device was prepared.

### (Configuration of Organic EL Device of Example 1)

Moisture barrier layer: SiN Nₓ with a thickness of 300 nm
Moisture absorbing layer: B₂O₃ with a thickness of 60 nm
Cathode: Mg—Ag alloys with a thickness of 5 nm
Electron injection layer: LiF with a thickness of 1 nm
Light emitting layer: Alq₃ with a thickness of 60 nm
Hole transport layer: α-NPD with a thickness of 30 nm
Hole injection layer: HATCN with a thickness of 40 nm
Anode: Al with a thickness of 150 nm
Substrate: glass substrate

### Example 2

An organic EL device was prepared in the same manner as that in Example 1 except that a mixed gas of nitrogen gas (N₂) and oxygen gas (O₂) was used as the reactant gas at the time of forming the moisture barrier layer. The moisture barrier layer of the organic EL device obtained in Example 2 is composed of SiOₓN_{y} (silicon nitride oxide) with a thickness of 300 nm.

### Example 3

An organic EL element was formed in the same manner as that in Example 1, and on the surface of the cathode of the element, a moisture absorbing layer was formed by allowing B₂O₃ (boron oxide) to be vapor deposited under vacuum to 60 nm in thickness.

On the surface of the moisture absorbing layer, an intermediate layer was formed by allowing BₓN_{y} (boron nitride) to be plasma vapor deposited under vacuum to 10 nm on thickness. For the plasma vapor deposition at the time of forming the intermediate layer, a pressure gradient-type plasma gun was used as a plasma source, boron particles were used as an evaporation source, nitrogen gas (N₂) was used as reaction gas, and a vapor deposition rate was 10 nm/minute.

On the surface of the intermediate layer, a moisture barrier layer was formed by allowing SiN_{X} (silicon nitride) to be plasma vapor deposited under vacuum to 300 nm in thickness. For the plasma vapor deposition at the time of forming the moisture barrier layer, a pressure gradient-type plasma gun was used as a plasma source, silicon particles were used as an evaporation source, nitrogen gas (N₂) was used as reaction gas, and a vapor deposition rate was 50 nm/minute.

In this manner, a top-emission type organic EL device was prepared.

### (Configuration of Organic EL Device of Example 3)

Moisture barrier layer: SiN Nₓ with a thickness of 300 nm
Intermediate Layer: BₓN_{y} with a thickness of 10 nm
Moisture absorbing layer: B₂O₃ with a thickness of 60 nm
Cathode: Mg—Ag alloys with a thickness of 5 nm
Electron injection layer: LiF with a thickness of 1 nm
Light emitting layer: Alq₃ with a thickness of 60 nm
Hole transport layer: α-NPD with a thickness of 30 nm
Hole injection layer: HATCN with a thickness of 40 nm
Anode: Al with a thickness of 150 nm
Substrate: glass substrate

### Example 4

An organic EL device was prepared in the same manner as that in Example 3 except that a mixed gas of nitrogen gas (N₂) and oxygen gas (O₂) was used as the reactant gas at the time of forming the moisture barrier layer. The moisture barrier layer of the organic EL device obtained in Example 4 is composed of SiOₓN_{y} (silicon nitride oxide) with a thickness of 300 nm.

### Comparative Example 1

An organic EL device was prepared in the same manner as that in Example 1 except that oxygen gas was used as the reactant gas at the time of forming the moisture barrier layer. The moisture barrier layer of the organic EL device obtained in Comparative Example 1 is composed of SiOₓ (silicon oxide) with a thickness of 300 nm.

### Comparative Example 2

An organic EL device was prepared in the same manner as that in Example 1 except that in place of the moisture absorbing layer in Example 1, a moisture absorbing layer was formed by allowing BaO (barium oxide) to be vapor deposited under vacuum to 60 nm in thickness.

### Comparative Example 31

An organic EL device was prepared in the same manner as that in Example 1 except that in place of the moisture absorbing layer in Example 1, a moisture absorbing layer was formed by allowing CaO (calcium oxide) to be vapor deposited under vacuum to 60 nm in thickness.

### Comparative Example 4

An organic EL device was prepared in the same manner as that in Example 3 except that oxygen gas was used as the reactant gas at the time of forming the moisture barrier layer. The moisture barrier layer of the organic EL device obtained in Comparative Example 4 is composed of SiOₓ (silicon oxide) with a thickness of 300 nm.

### Comparative Example 5

An organic EL device was prepared in the same manner as that in Example 3 except that in place of the moisture absorbing layer in Example 3, a moisture absorbing layer was formed by allowing BaO (barium oxide) to be vapor deposited under vacuum to 60 nm in thickness.

### [Confirmation of B—N Bond]

The moisture barrier layer of respective organic EL devices obtained in Example 1 and Example 2 was subjected to ion beam etching over a certain period of time in the thickness direction from the surface thereof, and the composition thereof was measured by X-ray photoelectron spectroscopy (XPS). As a result of analyzing the chemical structure of a boundary between the moisture barrier layer and the moisture absorbing layer on the basis of the measurement results, the existence of the B—N bond at a boundary between the moisture barrier layer and the moisture absorbing layer has been confirmed.

### [Measurement of Light Emission Life of Organic EL Device]

An organic EL device from each of Examples and Comparative Examples was incorporated in an experimental circuit, stored at 60° C. and 90% RH, and made to emit light over a long period of time by applying a voltage. The brightness at the initial stage of light emission was set to 100%, and time until the brightness decreased to 70% was measured.

The results thereof are shown in Table 1.

TABLE 1

| | Moisture | Intermediate | Moisture- | Time |
|---|---|---|---|---|
| | Absorbing | Layer | barrier | elapsed |
| | Layer | (BN Layer) | Layer | (h) |
| Example 1 | B₂O₂ | None | SiNx | 600 |
| Example 2 | B₂O₃ | None | SiOxNy | 500 |
| Example 3 | B₂O₂ | Present | SiNx | 800 |
| Example 4 | B₂O₃ | Present | SiOxNy | 650 |
| Comparative | B₂O₂ | None | SiOx | 200 |
| Example 1 | | | | |
| Comparative | BaO | None | SiNx | 300 |
| Example 2 | | | | |
| Comparative | CaO | None | SiNx | 300 |
| Example 3 | | | | |
| Comparative | B₂O₂ | Present | SiOx | 300 |
| Example 4 | | | | |
| Comparative | BaO | Present | SiNx | 400 |
| Example 5 | | | | |

As evident from Table 1, the organic EL devices of Examples 1 to 4 emitted light over a relatively long period of time. In particular, the organic EL devices in Examples 1 and 3 allowing the moisture barrier layer to be constituted of a nitride had a longer light emitting time than those in Examples 2 and 4 allowing the moisture barrier layer to be constituted of a nitride oxide. On the other hand, with regard to the organic EL devices in Comparative Examples 1 and 4 not allowing a nitrogen compound to be contained in the moisture barrier layer and the organic EL devices in Comparative Examples 2, 3 and 5 not allowing a boron compound to be contained in the moisture absorbing layer, the light emission was lowered in a short period of time.

Moreover, the organic EL devices in Examples 3 and 4 including an intermediate layer containing a B—N compound had a longer light emitting time than those in Examples 1 and 2 not including an intermediate layer. This reveals that the intermediate layer is especially useful for a prolonged light emitting time of the organic EL device.

### INDUSTRIAL APPLICABILITY

The organic EL device of the present invention can be used for illuminating devices, image displays, or the like.

1 Organic EL device, 2 Support substrate, 3 Organic EL element, 41, 42 Moisture absorbing layer, 51, 52 Moisture barrier layer, 6 Intermediate layer

1. An organic electroluminescence device comprising:
a support substrate;
an organic electroluminescence element provided on the support substrate;
a moisture absorbing layer which is provided on the organic electroluminescence element and which contains a boron compound; and
a moisture-barrier layer which is provided on the moisture absorbing layer and which contains a nitrogen compound.

2. The organic electroluminescence device according to claim 1, wherein a B—N bond moiety exists between the moisture absorbing layer and the moisture-barrier layer, wherein the B—N bond moiety is formed by a bond of the boron compound and the nitrogen compound.

3. The organic electroluminescence device according to claim 1, further comprising:
an intermediate layer which is interposed between the moisture absorbing layer and the moisture-barrier layer and which contains a compound having a B—N bond.

4. The organic electroluminescence device according to claim 3, wherein the compound having a B—N bond contains boron nitride.

5. The organic electroluminescence device according to claim 3, wherein the intermediate layer is formed by a plasma vacuum vapor deposition method.

6. The organic electroluminescence device according to claim 1, wherein the boron compound contains boron oxide.

7. The organic electroluminescence device according to claim 1, wherein the nitrogen compound contains at least one kind selected from a nitride of a metal or a semimetal, a nitride oxide thereof, a nitride carbide thereof and a nitride carbide oxide thereof.

8. The organic electroluminescence device according to claim 1, wherein the nitrogen compound contains at least one kind selected from a nitride of silicon, a nitride oxide thereof, a nitride carbide thereof and a nitride carbide oxide thereof.

9. The organic electroluminescence device according to claim 1, wherein the moisture-barrier layer is formed by a plasma vacuum vapor deposition method.
